(19) United States
(12) Patent Application Publication
(10) Pub. No.: US 2010/0130021 A1
(43) Pub. Date: May 27, 2010

(54) METHOD FOR PROCESSING A SILICON-ON-INSULATOR STRUCTURE

(75) Inventors: Michael J. Ries, St. Charles, MO (US); Robert W. Standley, Chesterfield, MO (US); Jeffrey L. Libbert, O'Fallon, MO (US); Andrew M. Jones, Wildwood, MO (US); Gregory M. Wilson, Chesterfield, MO (US)

Correspondence Address: Richard A. Schuth (MEMC);Armstrong Teasdale LLP, One Metropolitan Square, Suite 2600, St. Louis, MO, 63102-2740, US

(73) Assignee: MEMC ELECTRONIC MATERIALS, INC., St. Peters, MO (US)

(21) Appl. No.: 12/623,863

(22) Filed: Nov. 23, 2009

Related U.S. Application Data
(60) Provisional application No. 61/118,222, filed on Nov. 26, 2008.

(51) Int. Cl. H01L 21/306

(52) U.S. Cl. 438/748; 257/E21.219

(57) ABSTRACT

A method is disclosed for processing the cleaved surface of a silicon-on-insulator structure. The silicon-on-insulator structures comprises a handle wafer, a silicon layer, and a dielectric layer between the handle wafer and the silicon layer. The silicon layer has a cleaved surface defining an outer surface of the structure. The methods disclosed include an etching process to reduce the time and cost required to process the silicon-on-insulator structure to remove the surface damage and defects formed when a portion of the donor wafer is separated along a cleave plane from the silicon-on-insulator structure. The method includes, annealing the structure, etching the cleaved surface, and performing a non-contact smoothing process on the cleaved surface.

### BACKGROUND

Semiconductor wafers are generally prepared from a single crystal ingot (e.g., a silicon ingot) which is trimmed and ground to have one or more flats or notches for proper orientation of the wafer in subsequent procedures. The ingot is then sliced into individual wafers. While reference will be made herein to semiconductor wafers constructed from silicon, other materials may be used as well, such as germanium or gallium arsenide.

One type of wafer is a silicon-on-insulator (SOI) wafer. An SOI wafer includes a thin layer of silicon atop an insulating layer (i.e., an oxide layer) which is in turn disposed on a silicon substrate. A silicon-on-insulator wafer is a type of silicon-on-insulator structure.

An example process of making an SOI wafer includes depositing a layer of oxide on a polished front surface of a donor wafer. Particles (e.g., hydrogen atoms or a combination of hydrogen and helium atoms) are implanted at a specified depth beneath the front surface of the donor wafer. The implanted particles form a cleave plane in the donor wafer at the specified depth at which they were implanted. The surface of the donor wafer is cleaned to remove organic compounds deposited on the wafer during the implantation process.

The front surface of the donor wafer is then bonded to a handle wafer to form a bonded wafer through a hydrophilic bonding process. The donor wafer and handle wafer are bonded together by exposing the surfaces of the wafers to a plasma containing, for example, oxygen or nitrogen. Exposure to the plasma modifies the structure of the surfaces in a process often referred to as surface activation. The wafers are then pressed together and a bond is formed therebetween. This bond is relatively weak, and must be strengthened before further processing can occur.

In some processes, the hydrophilic bond between the donor wafer and handle wafer (i.e., a bonded wafer) is strengthened by heating or annealing the bonded wafer pair at temperatures between approximately 300° C. and 500° C. The elevated temperatures cause the formation of covalent bonds between the adjoining surfaces of the donor wafer and the handle wafer, thus solidifying the bond between the donor wafer and the handle wafer. Concurrently with the heating or annealing of the bonded wafer, the particles earlier implanted in the donor wafer weaken the cleave plane. A portion of the donor wafer is then separated (i.e., cleaved) along the cleave plane from the bonded wafer to form the SOI wafer.

The bonded wafer is first placed in a fixture in which mechanical force is applied perpendicular to the opposing sides of the bonded wafer in order to pull a portion of the donor wafer apart from the bonded wafer. According to some methods, suction cups are utilized to apply the mechanical force. The separation of the portion of the donor wafer is initiated by applying a mechanical wedge at the edge of the bonded wafer at the cleave plane in order to initiate propagation of a crack along the cleave plane. The mechanical force applied by the suction cups then pulls the portion of the donor wafer from the bonded wafer, thus forming an SOI wafer. According to other methods, the bonded pair may instead be subjected to an elevated temperature over a period of time to separate the portion of the donor wafer from the bonded wafer. Exposure to the elevated temperature causes initiation and propagation of a crack along the cleave plane, thus separating a portion of the donor wafer.

The resulting SOI wafer comprises a thin layer of silicon (the portion of the donor wafer remaining after cleaving) disposed atop the oxide layer and the handle wafer. The cleaved surface of the thin layer of silicon has a rough surface that is ill-suited for end-use applications. The damage to the surface may be the result of the particle implantation and the resultant dislocations in the crystal structure of the silicon. Accordingly, additional processing is required to smooth the cleaved surface.

To smooth and thin the surface layer of silicon (i.e., cleaved surface), previous methods utilized combinations of annealing, chemical-mechanical polishing, high-temperature gaseous etching (i.e., epitaxial-smoothing (epi-smoothing)), or the formation of a sacrificial oxide layer on the cleaved surface. Current pre-epitaxial smoothing anneal (PESA) processes subject the SOI wafer to an elevated temperature (1000° C. to 1200° C.) for several hours. The elevated temperature heals the cleaved surface of the SOI wafer by permitting the crystal structure of the silicon to reorient the dislocations present therein.

While the PESA process often significantly reduces the damage present on the cleaved surface, additional processing is required to reduce the thickness of the cleaved surface to a desired level and to smooth the surface to a desired surface quality. Accordingly, the processing of the cleaved surface of the SOI wafer is a time-consuming and costly process.

Thus, there remains an unfulfilled need for a wafer surface treatment method that addresses the disadvantages of current treatment operations and is suitable for use in wafer processing operations utilizing bonded wafers.

### BRIEF SUMMARY

A first aspect is a method for processing a silicon-on-insulator structure. The silicon-on-insulator structure has a handle wafer, a silicon layer, and a dielectric layer between the handle wafer and the silicon layer. The silicon layer has a cleaved surface defining an outer surface of the structure. The method comprises annealing the cleaved surface, etching the cleaved surface, and performing a non-contact smoothing process on the cleaved surface.

Another aspect is a method for processing a silicon-on-insulator structure. The silicon-on-insulator structure has a handle wafer, a silicon layer, and a dielectric layer between the handle wafer and the silicon layer. The silicon layer has a cleaved surface defining an outer surface of the structure. The method comprises etching the cleaved surface by removing at least some of the silicon layer and performing a non-contact smoothing process on the cleaved surface.

Another aspect is a method for processing a silicon-on-insulator structure. The silicon-on-insulator structure has a handle wafer, a silicon layer, and a dielectric layer between the handle wafer and the silicon layer. The silicon layer has a cleaved surface defining an outer surface of the structure. The method comprises etching the cleaved surface of the structure and annealing the structure.

Various refinements exist of the features noted in relation to the above-mentioned aspects. Further features may also be incorporated in the above-mentioned aspects as well. These refinements and additional features may exist individually or in any combination. For instance, various features discussed below in relation to any of the illustrated embodiments may be incorporated into any of the above-described aspects, alone or in any combination.

### BRIEF DESCRIPTION OF THE DRAWINGS

FIG. 1A is a top plan view of a donor silicon wafer.

FIG. 1B is a cross-sectional view of the donor silicon wafer of FIG. 1B.

FIG. 2 is a cross-sectional view of the donor silicon wafer undergoing ion implantation.

FIG. 3 is a cross-sectional view of a bonded wafer comprising the donor silicon wafer bonded to a handle silicon wafer.

FIG. 4 is a cross-sectional view of the bonded wafer of FIG. 3 after a portion of the donor wafer has been removed.

FIG. 5 is a cross-sectional view of the bonded wafer of FIG. 4 after processing of a cleaved surface of the bonded wafer.

FIG. 6 is a schematic diagram depicting a wafer spin etcher.

FIG. 7 is a flow diagram depicting a method for processing an SOI wafer.

FIG. 8 is a flow diagram depicting a method for processing an SOI wafer.

FIG. 9 is a flow diagram depicting a method for processing an SOI wafer.

### DETAILED DESCRIPTION

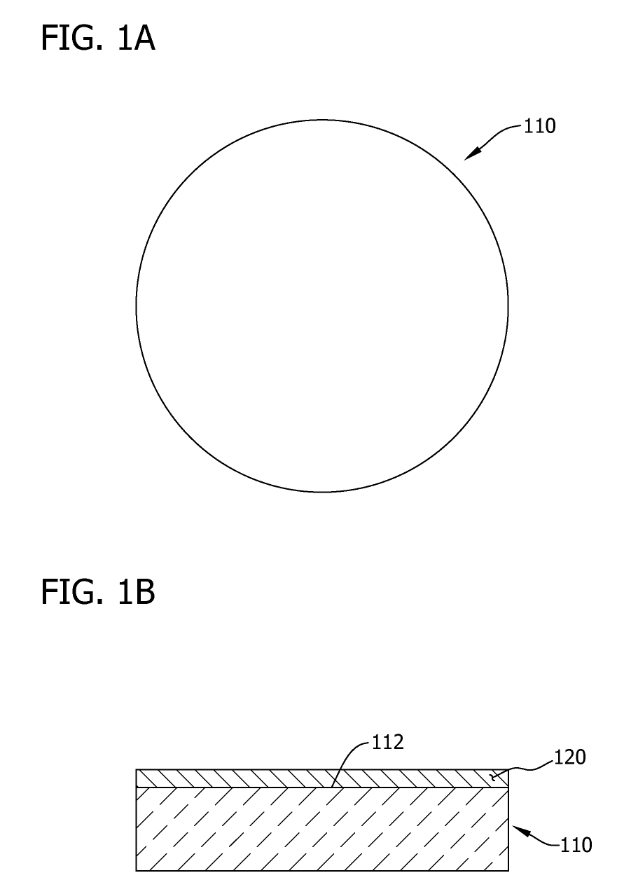

Referring initially to FIGS. 1A and 1B, a donor wafer 110 and an oxide layer 120 are depicted. FIG. 1A is a top plan view of the donor wafer 110, while FIG. 1B is a cross-sectional view of the donor wafer. The oxide layer 120 is bonded to a front surface 112 of the donor wafer 110. The oxide layer 120 can be grown atop the front surface 112 by subjecting the donor wafer 110 to an atmosphere suitable for the growth of the oxide layer. Alternatively, the oxide layer 120 can be deposited on the front surface 112 through any known chemical deposition process and functions as an insulator (i.e., a dielectric).

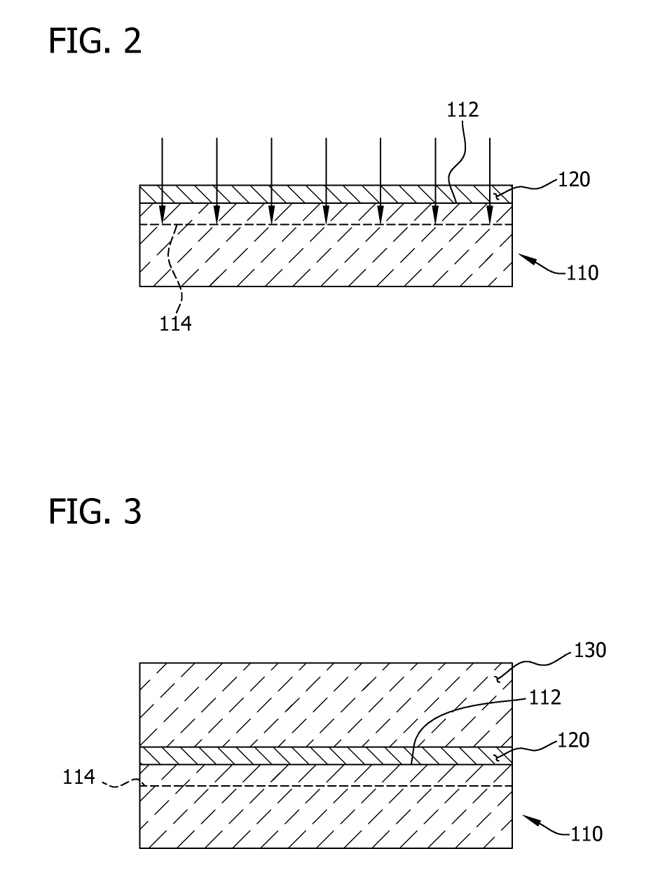

FIG. 2 is a cross-sectional view of the donor wafer 110 being implanted with particles (e.g., hydrogen atoms or a combination of both hydrogen atoms and helium atoms). The donor wafer 110 is implanted with particles to a specified depth below the front surface 112 of the donor wafer 110. In some embodiments, the particles are hydrogen or helium ions which are implanted through an ion implantation process. A cleave plane 114 is then formed beneath the front surface 112 of the donor wafer 120 at a distance from the front surface equal to specified depth to which the particles were implanted. The cleave plane 114 defines a plane through the donor wafer 110 where the donor wafer is substantially weakened by the implantation of the ions upon subsequent heating of the donor wafer.

FIG. 3 is a cross-sectional view of the donor wafer 110 and a handle wafer 130. The donor wafer 110 and handle wafer 130 are bonded together in accordance with any suitable method, such as a hydrophilic bond. The donor wafer and handle wafer are bonded together by exposing the surfaces of the wafers to a plasma containing, for example, oxygen or nitrogen. The surfaces of the wafers are modified by the exposure to the plasma in a process often referred to as surface activation. The wafers are then pressed together and a bond is formed therebetween. This bond is weak, and must be strengthened before further processing can occur.

Together, the donor wafer 110 and handle wafer 130 form a bonded wafer 140. In some processes, the hydrophilic bond between the donor wafer and handle wafer (i.e., a bonded wafer) is strengthened by heating or annealing the bonded wafer pair at temperatures between approximately 300° C. and 500° C. The elevated temperatures cause formation of covalent bonds between the adjoining surfaces of the donor wafer and the handle wafer, thus solidifying the bond between the donor wafer and the handle wafer. Concurrently with the heating or annealing of the bonded wafer, the particles earlier implanted in the donor wafer begin to move and weaken the cleave plane.

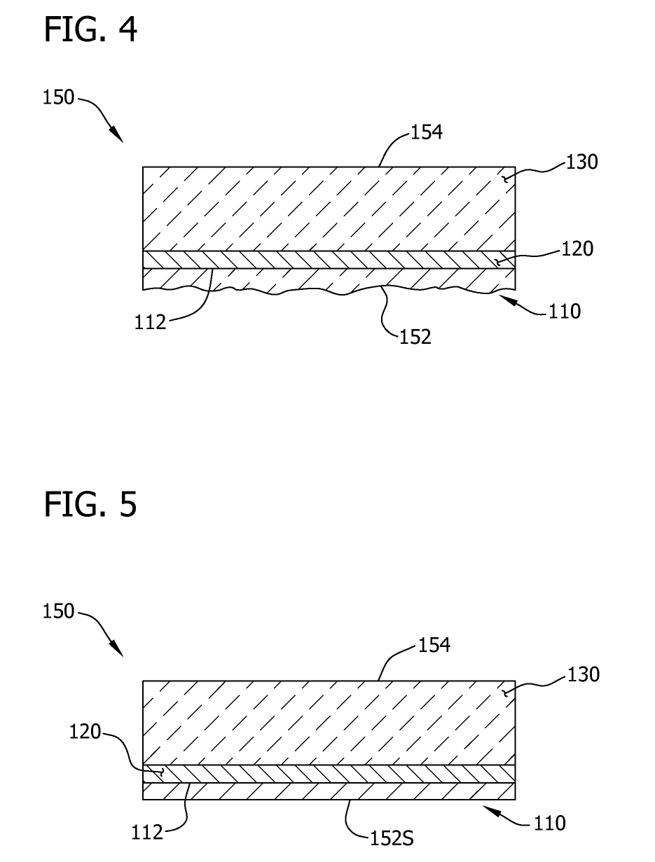

FIG. 4 is a cross-sectional view of the bonded wafer 140 depicted in FIG. 3. A portion of the bonded wafer 140 has been removed in the depiction in FIG. 4 during a cleaving process. According to other methods, the bonded pair may instead be subjected to an elevated temperature over a period of time to separate the portion of the donor wafer from the bonded wafer. Exposure to the elevated temperature functions to initiate and propagate a crack along the cleave plane, thus separating a portion of the donor wafer.

Because the cleave plane 114 has been substantially weakened by the implantation of ions, it defines a boundary along which the wafer readily separates when a force is applied thereto. According to some embodiments, the bonded wafer 140 is first placed in a fixture in which mechanical force is applied perpendicular to the opposing sides of the bonded wafer in order to pull the portion of the donor wafer apart from the bonded wafer. In one embodiment, suction cups are used to apply the mechanical force. The separation of the portion of the donor wafer 110 is initiated by applying a mechanical wedge at the edge of the bonded wafer at the cleave plane in order initiate propagation of a crack along the cleave plane. Due to the weakened structure of the cleave plane, the crack propagates along the cleave plane 114 until the bonded 140 wafer has separated into two pieces along the cleave plane. The mechanical force applied by the suction cups then pulls the bonded wafer 140 into two pieces. One piece is comprised only of a portion of the donor wafer 110. The other piece is comprised of the handle wafer 130 and the portion of the donor wafer 110 bonded thereto and forms a silicon-on-insulator (SOI) wafer, referred to generally as 150.

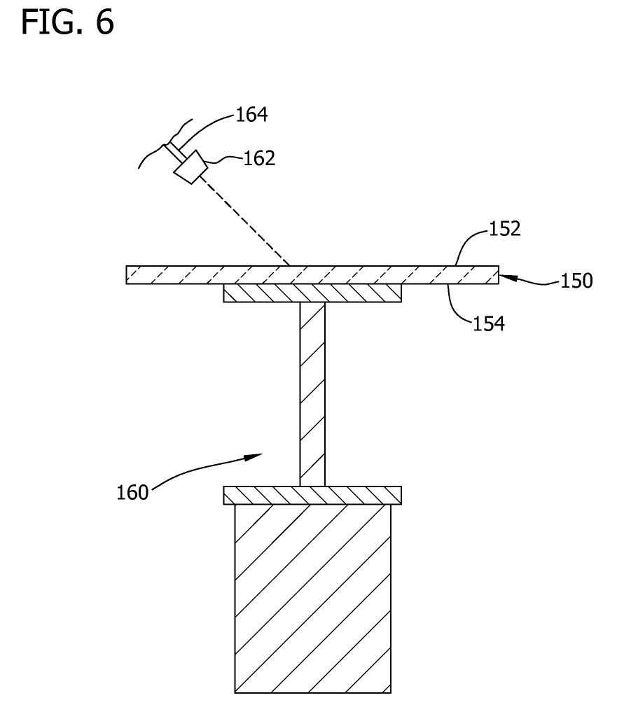

A cleaved surface 152 of the SOI wafer 150 defines the surface which results after the separation of the bonded wafer 140 along the cleave plane 114. The cleaved surface 152 has a damaged surface as a result of the separation along the cleave plane 114 that, without further processing, renders the surface ill-suited for end-use applications. Accordingly, the cleaved surface 152 is subjected to additional processing steps to repair the damage and smooth the cleaved surface 152. The processing of the SOI wafer 150 is discussed in greater detail below in relation to FIGS. 6-9.

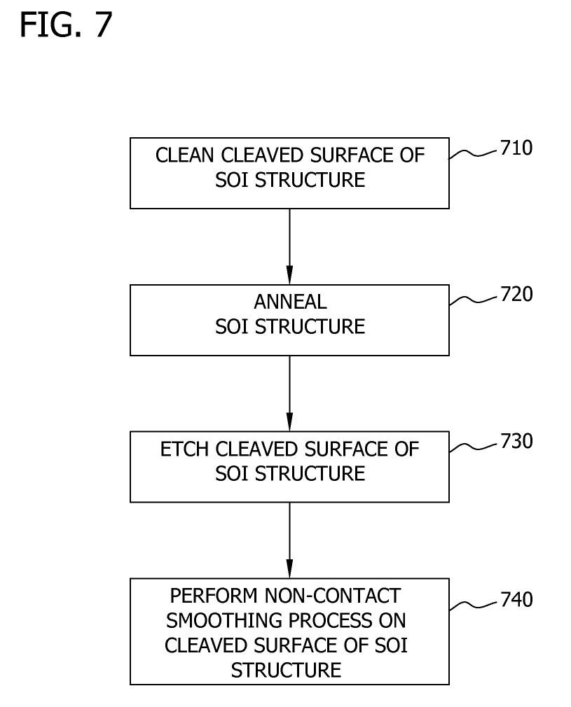

FIG. 5 is a cross-sectional view of the SOI wafer 150 after processing of the cleaved surface 152, resulting in a smoothed cleaved surface 152S. As can be seen in FIG. 5, the smoothed cleaved surface 152S has a smooth surface with a uniform profile. The processing of the SOI wafer 150 is discussed in greater detail in relation to FIGS. 7-9, below.

A wafer spin etcher, referred to generally as 160 as depicted in FIG. 6, is utilized to uniformly distribute an etchant over the cleaved surface 152 of the SOI wafer 150. The wafer spin etcher 160 rotates the SOI wafer 150 about an axis perpendicular to the cleaved surface 152 and intersecting the SOI wafer at approximately its center point. A back surface 154 is suitably connected to the wafer spin etcher 160. The angular velocity and acceleration of the wafer spin etcher 160 may be varied to alter the flow of etchant across the cleaved surface 152. For example, the angular velocity may be increased to increase the rate at which etchant is dispersed from the cleaved surface 152. Alternatively, the angular velocity may be decreased to slow the rate at which etchant is dispersed from the cleaved surface 152.

The wafer spin etcher 160 comprises a nozzle 162 to output a volume of liquid etchant and directs it at the cleaved surface 152. The nozzle 162 is coupled to a boom 164. The boom 164 can move horizontally, vertically, tilt, or telescope.

The nozzle 162 may expel etchant in a variety of patterns or modes. For example, the nozzle 162 may expel etchant in a generally laminar flow pattern, or it may expel it in a non-laminar, turbulent flow pattern. The mode that the etchant is expelled from the nozzle 162 may be altered, for example, based on the particular type of etchant being utilized. Additionally, the mode can be altered to affect the amount of time in which etchant is in contact with the cleaved surface 152.

The etchant expelled by the nozzle 162 may be a mixture of hydrofluoric acid and acetic acid. In some embodiments, the etchant is a solution of hydrofluoric acid diluted in de-ionized water and a surfactant or viscosity modifier (e.g., acetic acid) is added to adjust the rate at which the etchant etches the SOI wafer 150.

Generally, the acidic etchant is in the form of an aqueous solution comprising a source of hydrogen ions. The source of the hydrogen ions may be selected from the group comprising hydrofluoric acid, nitric acid, phosphoric acid, acetic acid, sulfuric acid, hydrochloric acid, citric acid, oxalic acid, propionic acid, permanganic acid, and combinations thereof. Typically, the source of hydrogen ions is present in the etchant at a concentration of at least about 40 wt %, more typically at least about 50 wt %, still more typically at least about 60 wt % and, even more typically, at least about 70 wt % (e.g., at least about 80 wt %, or at least about 90 wt %). In various embodiments, the acidic etchant comprises essentially water and the source of hydrogen ions. In various other embodiments, the acidic etchant comprises one or more additives along with the sources of hydrogen ions.

The embodiments of FIGS. 7-9 described below each use an etching process to reduce the time and cost required to process an SOI wafer to remove the surface damage and defects formed when a portion of the donor wafer is separated along the cleave plane from the SOI wafer.

FIG. 7 is a flow diagram depicting a method for processing an SOI wafer cleaved from a bonded wafer. The SOI wafer has a cleaved surface and a back surface. The SOI wafer is one type of silicon-on-insulator structure and, as described above, has a handle wafer a silicon layer, and a dielectric layer between the handle wafer and the silicon layer. The SOI wafer is manufactured according to any number of methods, including those described in relation to FIGS. 1-4.

The method begins in block 710 with the cleaning of the cleaved surface of the SOI wafer. The cleaved surface comprises a layer of silicon. The cleaved surface can be cleaned according to a variety of methods known to those skilled in the art. Loose material is removed from the cleaved surface during the cleaning at block 710. In other embodiments, the method does not begin with the cleaning of the cleaved surface. Instead, the method begins with annealing the SOI wafer, and the cleaved surface of the SOI wafer is not cleaned prior to annealing.

In block 720, the SOI wafer is annealed. According to some embodiments, the SOI wafer may be annealed by being placed in an oxidizing environment, thus resulting in the generation of a layer of oxide atop the cleaved surface. In other embodiments, the SOI wafer may be annealed by being placed in an inert atmosphere (e.g., argon or nitrogen) or an atmosphere containing argon, hydrogen, or a mixture thereof. The annealing is suitably a conventional rapid thermal anneal (RTA) process, a batch process, or other suitable annealing process.

The annealing of the SOI wafer strengthens the bond between the components of the SOI wafer (i.e., the handle wafer and the portion of the donor wafer bonded thereto). In previous methods, the process of annealing the SOI wafer prior to a non-contact smoothing operation is referred to as a pre-epi smoothing anneal (PESA). The PESA process is a relatively time-consuming and expensive operation as temperatures in the range of 1000° C. to 1200° C. for several hours are required. The elevated temperature heals the cleaved surface of the SOI wafer by permitting the crystal structure of the silicon to reorient the dislocations present therein. The healing of the cleaved surface may enable optimization of the annealing step, such as by enabling reduction of the time and/or temperature of the annealing step. Such optimization will reduce the cost of the process.

The annealing performed in block 720 also functions to strengthen the bond between the layers of the SOI wafer. In some embodiments, the bonding process used to bond the donor wafer and the handle wafer is of the type that requires exposure to elevated temperatures.

The cleaved surface of the SOI wafer is etched in block 730. The etching comprises removing at least some of the layer of silicon on the cleaved surface. By removing at least some of the layer of silicon, the cleaved surface is smoothed. An etchant is dispersed across the cleaved surface of the SOI wafer to improve the smoothness of the cleaved surface. The etchant removes a portion of a layer of silicon disposed on the cleaved surface by way of a chemical reaction with the etchant. According to some embodiments the SOI wafer is placed in a wafer spin etcher as described in relation to FIG. 6 and rotated about an axis perpendicular to the cleaved surface. Etchant is dispersed onto the cleaved surface while the SOI wafer is rotated.

As discussed above in relation to FIG. 6, the method in which the etchant is dispersed may be modified in order to affect the amount of time that the etchant remains in contact with the cleaved surface. Furthermore, the viscosity of the etchant may be modified by altering its composition (e.g., the ratio of the acetic acid in the etchant may be increased to increase the viscosity). The amount of time that the etchant remains in contact with the cleaved surface is proportional to the amount of silicon that is removed by the etchant from the cleaved surface. Accordingly, by increasing the amount of time that the etchant is in contact with the cleaved surface of the SOI wafer, more silicon is removed from the cleaved surface.

In block 740 a non-contact smoothing process is performed on the cleaved surface of the SOI wafer. In some embodiments, the non-contact smoothing process comprises annealing the SOI wafer in an inert atmosphere (e.g., argon), an atmosphere containing argon, hydrogen, or a mixture thereof, and/or etching it with a gaseous etchant (e.g., hydrochloric acid). In previous methods, this process is often referred to as epi-smoothing. As previous methods do not use an etchant step as discussed in block 730, the epi-smoothing process is relied upon to smooth the cleaved surface of the SOI wafer. Like the PESA process, the epi-smoothing operation is time-consuming and costly. By etching the cleaved surface of the SOI wafer in block 730, the amount of time required to process the SOI wafer in block 730 is significantly reduced. The amount of gaseous etchant required is also significantly reduced. Following the completion of block 740, the SOI wafer is in a suitable condition for an end-use application.

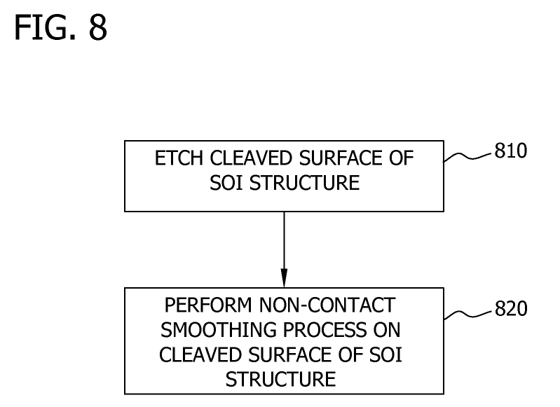

FIG. 8 is a flow diagram depicting a method for processing an SOI wafer having a cleaved surface and a back surface. In this embodiment, a reduced-duration non-contact smoothing process (e.g., epi-smoothing) is retained from the previous methods.

The method begins in block 810 with the etching of the cleaved surface of the SOI wafer. The etching removes at least some of a layer of silicon on the cleaved surface. In some embodiments, the etching substantially removes any oxide present on the cleaved surface. In other embodiments, a thin layer of oxide remains on the cleaved surface after etching. In other words, the etching process is performed to leave a thin layer of oxide on the cleaved surface. This thin layer may include or constitute a passivation coating or layer on the cleaved surface. As discussed in relation to FIG. 7, etchant is applied to the cleaved surface of the SOI wafer while it is rotated in a wafer spin etcher. The thickness of the layer of silicon that is removed by the etchant can be selected or adjusted by altering the composition of the etchant, the angular velocity of the rotation of the SOI wafer, or the flow characteristics of the nozzle head through which etchant is dispersed onto the cleaved surface.

In block 820, a non-contact smoothing process is performed on the cleaved surface of the SOI wafer. The non-contact smoothing process of this embodiment comprises annealing the SOI wafer in an inert atmosphere. In embodiments where a thin oxide layer remains on the cleaved surface after etching, annealing the SOI wafer may remove the thin oxide layer. As described above, the non-contact smoothing process may comprise subjecting the SOI wafer to an epi-smoothing process, during which the cleaved surface is brought into contact with a gaseous etchant (e.g., hydrochloric acid) at an elevated temperature. The amount of etchant is reduced from that utilized in previous methods and the time required for the acid to be in contact with the SOI wafer is reduced as well. Following the completion of block 820, the SOI wafer is in a suitable condition for an end-use application.

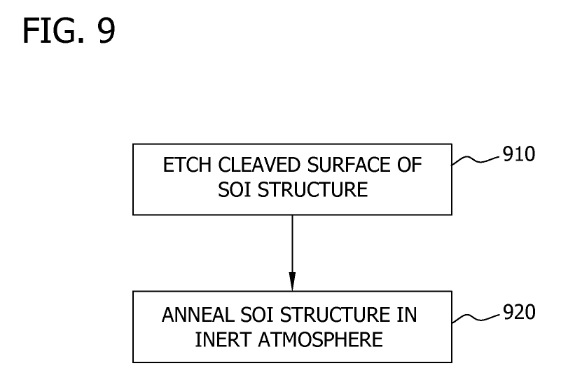

FIG. 9 is a flow diagram depicting a method for processing an SOI wafer. The SOI wafer has a cleaved surface and a back surface. The processes utilized in previous methods, subjects the SOI wafer to a limited-duration anneal after the etching is complete. The method begins in block 910 with the etching of the cleaved surface of the SOI wafer. The wafer is etched in a substantially similar manner to that described above.

In block 920 the SOI wafer is annealed in an inert atmosphere (e.g., argon) or an atmosphere containing argon, hydrogen, or a mixture thereof. According to other embodiments, the atmosphere may be an oxidizing atmosphere, thus resulting in the formation of an oxide film on the cleaved surface. The annealing operation reduces defects or non-uniformities in the cleaved surface and strengthens the bonds between the layers of the SOI wafer, as well as repairing damage resultant from the ion implantation process.

The embodiment of FIG. 7 retains the use of processes employed in previous known methods to smooth the cleaved surface of the SOI wafer, but reduces the length and temperatures required in the processes, thus reducing the overall cost of processing the SOI wafer. The embodiment of FIG. 8 only retains a reduced-duration epi-smoothing process from the previous methods. The embodiment of FIG. 9 eliminates all of the processes utilized in previous methods, and subjects the SOI wafer to a limited-duration anneal after the etching is complete. The limited-duration anneal strengthens the bond between the layers of the SOI wafer and in some embodiments, smoothes the wafer to the desired roughness level.

The selection of which embodiment to use can be based on the level of surface smoothness and repair of surface damage achieved by etching the cleaved surface and the required level of surface smoothness for an end-use application. For example, if the level of surface smoothness and repair of surface damage resulting from the etching of the cleaved surface is likely to meet or exceed the requirements for the end-use application, the embodiment described in relation to FIG. 9 may be used. However, if after etching the level of uniformity of the etched surface is not likely to meet the requirements for the end-use application, the SOI wafer may be subjected to the embodiments described in relation to FIGS. 7 and 8.

When introducing elements of the present invention or the embodiment(s) thereof, the articles “a”, “an”, “the” and “said” are intended to mean that there are one or more of the elements. The terms “comprising”, “including” and “having” are intended to be inclusive and mean that there may be additional elements other than the listed elements.

As various changes could be made in the above constructions without departing from the scope of the invention, it is intended that all matter contained in the above description and shown in the accompanying drawing[s] shall be interpreted as illustrative and not in a limiting sense.

What is claimed is:

1. A method for processing a silicon-on-insulator structure comprising a handle wafer, a silicon layer, and a dielectric layer between the handle wafer and the silicon layer, the silicon layer having a cleaved surface defining an outer surface of the structure, the method comprising the steps of:
annealing the structure;
etching the cleaved surface; and
performing a non-contact smoothing process on the cleaved surface.

2. The method of claim 1 wherein the etching step comprises removing at least some of the silicon layer of the structure.

3. The method of claim 2 wherein the etching step comprises directing etchant against the silicon layer of the structure to remove at least some of the silicon layer.

4. The method of claim 3 wherein the etching step includes rotating the structure on a spin etcher while the etchant is directed against the silicon layer.

5. The method of claim 4 wherein the etching step includes directing etchant in a laminar flow against the silicon layer.

6. The method of claim 4 wherein the etching step includes directing etchant in a non-laminar flow against the silicon layer.

7. The method of claim 1 wherein the non-contact smoothing process comprises performing an epi-smoothing process on the cleaved surface.

8. The method of claim 1 wherein the non-contact smoothing process comprises annealing the structure in an inert atmosphere.

9. The method of claim 1 wherein the annealing step includes annealing the structure in an oxidizing environment.

10. The method of claim 1 wherein the annealing step includes placing the structure in an inert atmosphere comprising a mixture of argon and hydrogen.

11. The method of claim 1 wherein the annealing is a batch anneal process.

12. The method of claim 1 wherein the annealing step is a rapid thermal anneal.

13. The method of claim 1 further comprising cleaning the cleaved surface prior to annealing the structure.

14. A method of processing a silicon-on-insulator structure comprising a handle wafer, a silicon layer, and a dielectric layer between the handle wafer and the silicon layer, the silicon layer having a cleaved surface defining an outer surface of the structure, the method comprising the steps of:
etching the cleaved surface of the structure by removing at least some of the silicon layer of the structure; and
performing a non-contact smoothing process on the cleaved surface of the structure.

15. The method of claim 14 wherein the etching step substantially removes any oxide on the silicon layer.

16. The method of claim 14 wherein after the etching step includes allowing a thin layer of oxide to remain on the cleaved surface.

17. The method of claim 16 wherein the thin layer of oxide includes a passivation coating on the cleaved surface.

18. The method of claim 14 wherein the non-contact smoothing process comprises performing an epi-smoothing process on the cleaved surface.

19. The method of claim 14 wherein the non-contact smoothing process comprises annealing the structure in an inert atmosphere comprising argon.

20. The method of claim 14 wherein the non-contact smoothing process comprises annealing the structure in an atmosphere comprising a mixture of argon and hydrogen.

21. The method of claim 18 wherein the non-contact smoothing process comprises contacting the cleaved surface of structure with a gaseous etchant.

22. The method of claim 14 further comprising rotating the structure while etching the cleaved surface.

23. The method of claim 22 further comprising altering the altering the amount of the silicon layer removed by the etching by modifying at least one of: a composition of the etchant, a rate of rotation of the structure, and flow characteristics of a nozzle head through which etchant is dispersed onto the cleaved surface.

24. A method of processing a silicon-on-insulator structure comprising a handle wafer, a silicon layer, and a dielectric layer between the handle wafer and the silicon layer, the silicon layer having a cleaved surface defining an outer surface of the structure, the method comprising the steps of:
etching the cleaved surface of the structure; and
annealing the structure.

25. The method of claim 24 wherein the annealing step comprises placing the structure in an inert atmosphere comprising argon.

26. The method of claim 24 wherein the annealing step comprises placing the structure in an atmosphere comprising a mixture of argon and hydrogen.

27. The method of claim 24 wherein etching the cleaved surface of the structure comprises removing at least some of the silicon layer of the structure.

28. The method of claim 27 wherein the etching step substantially removes any oxide on the cleaved surface.

29. The method of claim 27 wherein the etching step includes allowing a thin layer of oxide to remain on the cleaved surface.

30. The method of claim 29 wherein the thin layer of oxide includes a passivation coating on the cleaved surface.

31. The method of claim 27 further comprising rotating the structure while etching the cleaved surface.

32. The method of claim 31 further comprising altering the altering the amount of the silicon layer removed by the etching by modifying at least one of: a composition of the etchant, a rate of rotation of the structure, and flow characteristics of a nozzle head through which etchant is dispersed onto the cleaved surface.
